(19) United States
(12) Patent Application Publication
(10) Pub. No.: US 2016/0021784 A1
(43) Pub. Date: Jan. 21, 2016

(54) Cooling Module for Electrical Components

(71) Applicant: CATERPILLAR INC., Peoria, IL (US)

(72) Inventors: Edward Choi, Edwards, IL (US); Chris J. Scolton, Edelstein, IL (US)

(73) Assignee: CATERPILLAR INC., Peoria, IL (US)

(21) Appl. No.: 14/331,752

(22) Filed: Jul. 15, 2014

(51) Int. Cl. H05K 7/20

(52) U.S. Cl. CPC H05K 7/20263

(57) ABSTRACT

A cooling module for an electrical component is provided. The cooling module includes a housing defining an interior space for receiving a coolant. A flow directing member is arranged in the interior space of the housing. The flow directing member includes a plate that is divided into a plurality of discrete cells arranged parallel to each other with adjacent cells being separated from each other by a dividing wall. Each cell has an inlet opening in the plate through which coolant is directed onto a surface of the plate and an outlet opening in the plate through which coolant is directed off the surface of the plate. Each cell has a plurality of fins arranged on the surface of the plate in a herringbone pattern.

### TECHNICAL FIELD

This patent disclosure relates generally to cooling devices and, more particularly, to a cooling module for electrical components that generate heat during operation.

### BACKGROUND

High performance electrical components can generate a significant amount of heat during operation. For example, machines having an electric drive can utilize power electronics such as insulated gate bipolar transistors (“IGBTs”) to provide high efficiency and rapid power switching. The IGBT modules and other electrical components associated with the electric drive can produce heat during operation. If not cooled adequately, this heat can adversely impact the reliability and performance capability of the associated electrical component.

To help ensure adequate operation and to increase the lifespan of IGBTs and other such electrical devices, a cooling unit or system may be provided to help dissipate the heat that is generated by such electrical devices. One method that is used to cool these types of electrical devices is mounting the electrical device to a cooling plate. The cooling plate may include upper and lower aluminum plates that define therebetween a passage through which coolant may flow. To help prevent the formation of air pockets between the upper plate and the base plate of the electrical device, a thermal interface material may be provided between the two plates. While the thermal interface material provides better thermal conductivity than an air pocket, the combination of the aluminum upper plate and the thermal interface material provides a higher thermal resistance than direct cooling arrangements where the flow of coolant is directly exposed to the base plate of the electrical device. Accordingly, optimal cooling may not be achieved.

Another example of a cooling unit that can be used to dissipate heat from electrical devices is disclosed in U.S. Pat. No. 7,360,582 (“the '582 patent”). The disclosed cooling unit includes a distributor for guiding liquid across a surface to be cooled. The distributor has a flow cell with a main flow channel formed as a meandering sequence of channel segments. The main flow channel also includes a bypass flow channel that allows the flow of fluid from the cell inlet to the cell outlet and interconnects the segments of the main flow channel.

The flow of cooling fluid through the cooling unit disclosed in the '582 patent and through other similar cooling units, however, does not provide optimal cooling performance. Moreover, the resistance to fluid flow that is generated by the pattern of channel segments can produce a significant pressure drop in the cooling fluid as it flows from the inlet to the outlet of the cooling unit. As will be appreciated, a higher pressure drop can lead to higher pump power requirements and a resultant increased system and operating costs. A higher pressure drop can also lead to higher stress on the various components of the cooling system associated with directing the coolant fluid through the system such as seals, gaskets and hoses.

### SUMMARY

In one aspect, the disclosure describes a cooling module for an electrical component. The cooling module includes an interior space for receiving a coolant. The housing has an inlet for directing coolant into the interior space and an outlet for removing coolant from the interior space. A flow directing member is arranged in the interior space of the housing, the flow directing member includes a plate that is divided into a plurality of discrete cells arranged parallel to each other. Adjacent cells are separated from each other by a dividing wall. Each cell has an inlet opening in the plate through which coolant is directed onto a surface of the plate and an outlet opening in the plate through which coolant is directed off the surface of the plate. Each cell has a plurality of fins arranged on the surface of the plate in a herringbone pattern. The plurality of fins includes a plurality of first fins arranged in a first row extending in a downstream direction from the inlet opening in the respective cell to the outlet opening in the respective cell and a plurality of second fins arranged in a second row extending in the downstream direction. Each first fin has an opposing second fin that together form a V-shape that is broken by a flow opening between the first and second fins. Each first and second fin is angled in a downstream direction as it extends from an edge of the cell towards a center of the cell.

In another aspect, the disclosure describes a cooling module for an electrical component. The cooling module includes a housing defining an interior space for receiving a coolant. The housing has an inlet for directing coolant into the interior space and an outlet for removing coolant from the interior space. A flow directing member is arranged in the interior space of the housing. The flow directing member includes a plate that is divided into a plurality of discrete cells arranged parallel to each other. Adjacent cells are separated from each other by a dividing wall having a plurality of openings therethrough such that the cells are fluidly connected to each other. Each cell has an inlet opening in the plate through which coolant is directed onto a surface of the plate and an outlet opening in the plate through which coolant is directed off the surface of the plate. Each cell has a plurality of fins arranged on the surface of the plate in a herringbone pattern. The plurality of fins includes a plurality of first fins arranged in a first row extending in a downstream direction from the inlet opening in the respective cell to the outlet opening in the respective cell and a plurality of second fins arranged in a second row extending in the downstream direction. Each first fin has an opposing second fin that together form a V-shape that is broken by a flow opening between the first and second fins. Each first and second fin is angled in a downstream direction as it extends from an edge of the cell towards a center of the cell. Each fin that is arranged next to one of the dividing walls is spaced from the respective dividing wall such that there is an opening between an end of the fin nearest the dividing wall and the dividing wall.

In yet another aspect, the disclosure describes a cooling assembly. The cooling assembly includes an electrical component including a base plate and a cooling module. The cooling module includes a housing having an open top. The housing is connected to the electrical component with the base plate extending over the open top of the housing. The housing defines an interior space for receiving a coolant. The housing has an inlet for directing coolant into the interior space and an outlet for removing coolant from the interior space. A flow directing member is arranged in the interior space of the housing. The flow directing member includes a plate arranged near the open top of the housing that is divided into a plurality of discrete cells arranged parallel to each other. Adjacent cells are separated from each other by a dividing wall having a plurality of openings therethrough such that the cells are fluidly connected to each other. Each cell has an inlet opening in the plate through which coolant is directed onto a surface of the plate and an outlet opening in the plate through which coolant is directed off the surface of the plate. Each cell has a plurality of fins arranged on the surface of the plate in a herringbone pattern. The plurality of fins includes a plurality of first fins arranged in a first row extending in a downstream direction from the inlet opening in the respective cell to the outlet opening in the respective cell and a plurality of second fins arranged in a second row extending in the downstream direction. Each first fin has an opposing second fin that together form a V-shape that is broken by a flow opening between the first and second fins. Each first and second fin is angled in a downstream direction as it extends from an edge of the cell towards a center of the cell. Each fin that is arranged next to one of the dividing walls is spaced from the respective dividing wall such that there is an opening between an end of the fin nearest the dividing wall and the dividing wall.

### BRIEF DESCRIPTION OF THE DRAWINGS

FIG. 1 is a top view of an exemplary electrical component connected to one embodiment of a cooling module according to the present disclosure.

FIG. 2 is a top view of the cooling module of FIG. 1 with the electrical component removed.

FIG. 3 is a top perspective view of the housing of the cooling module of FIG. 1.

FIG. 4 is a top perspective of the flow directing member of the cooling module of FIG. 1.

FIG. 5 is a partial top view of the flow directing member of the cooling module of FIG. 1.

FIG. 6 is a schematic, side sectional view of the electrical component and cooling module of FIG. 1.

### DETAILED DESCRIPTION

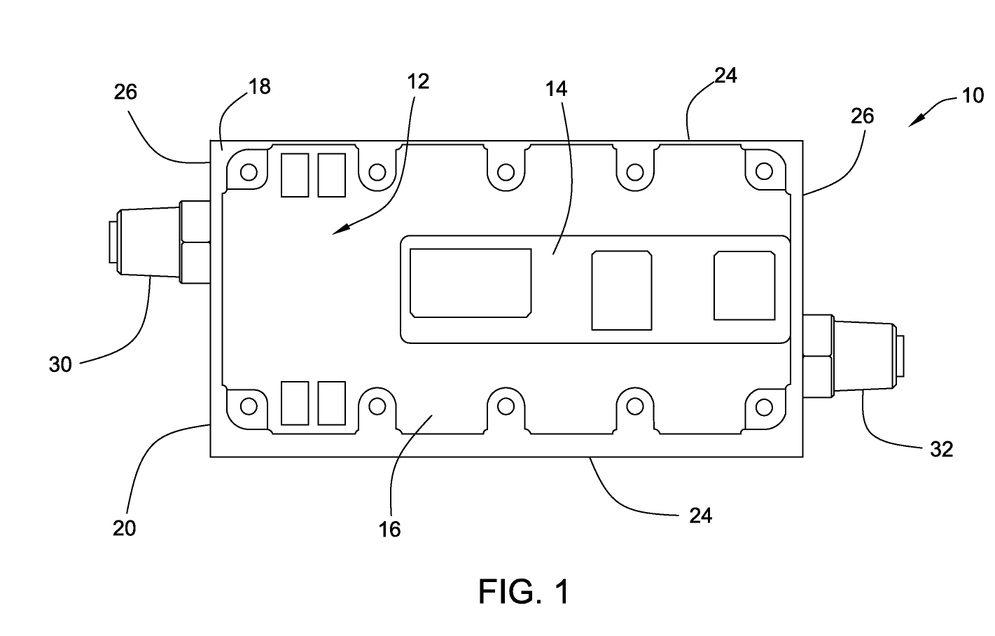

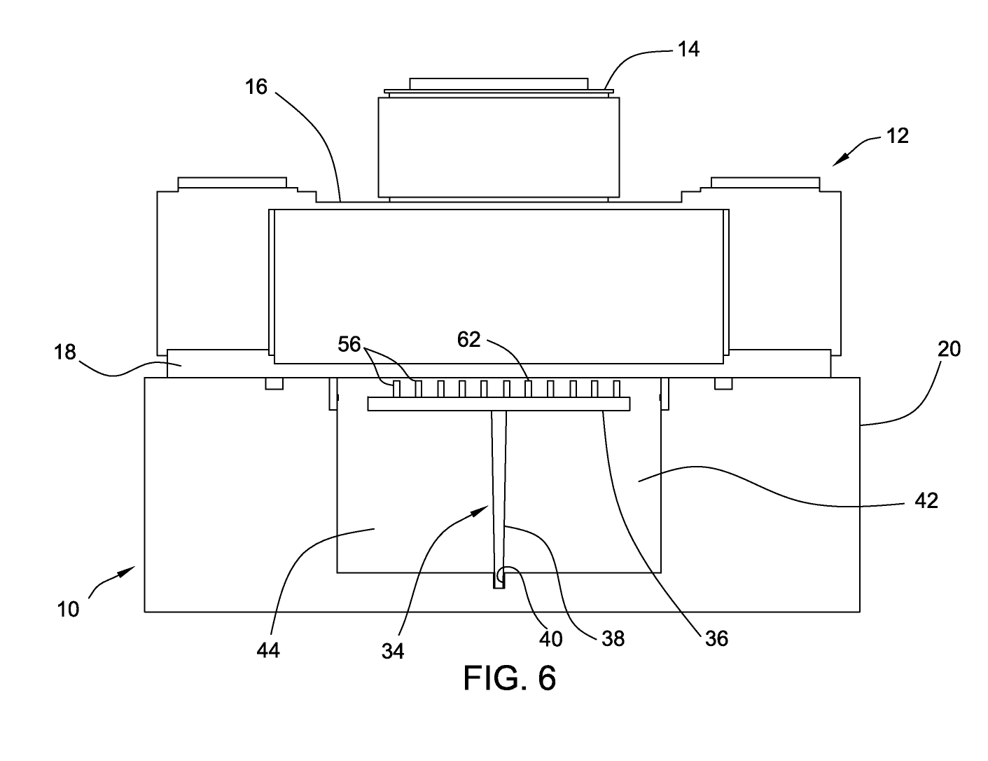

This disclosure generally relates to a cooling module that can be used to dissipate heat produced by an electrical component. With particular reference to FIG. 1, an exemplary embodiment of a cooling module 10 is shown connected to an electrical component 12. The electrical component 12 may be any electrical component that produces heat during operation. For example, the electrical component 12 may be an electrical component used in a power converter assembly for a multiple phase AC electric drive propulsion system in a machine, such as an automobile, truck, agricultural vehicle, work vehicle, wheel loader, dozer, loader, track-type tractor, grader, off-highway truck, locomotive, wind turbine or other work machine known to those skilled in the art. More specifically, the electrical component 12 can be one or more transistor based products, such as IGBT modules, used for power switching in the power converter assembly. IGBT modules are well known and widely used in electrical power systems. In this case, the illustrated electrical component 12 is an IGBT module and includes a die 14 that is mounted on a substrate 16 that is, in turn, connected to a base plate 18 (see also FIG. 6). The cooling module 10 combined with the electrical component 12 may be referred to herein as a cooling assembly.

As will be appreciated by those skilled in the art, the present disclosure can also apply to other electrical components including transistor based products, such as thyristers, diodes, and metal-oxide-semi-conductor field-effect transistors (“MOSFETS”). Additionally, the cooling module 10 of the present disclosure is not limited to use in an electric drive system for a machine. For example, the cooling module 10 could also be used to cool one or more electrical components in an electric power generator.

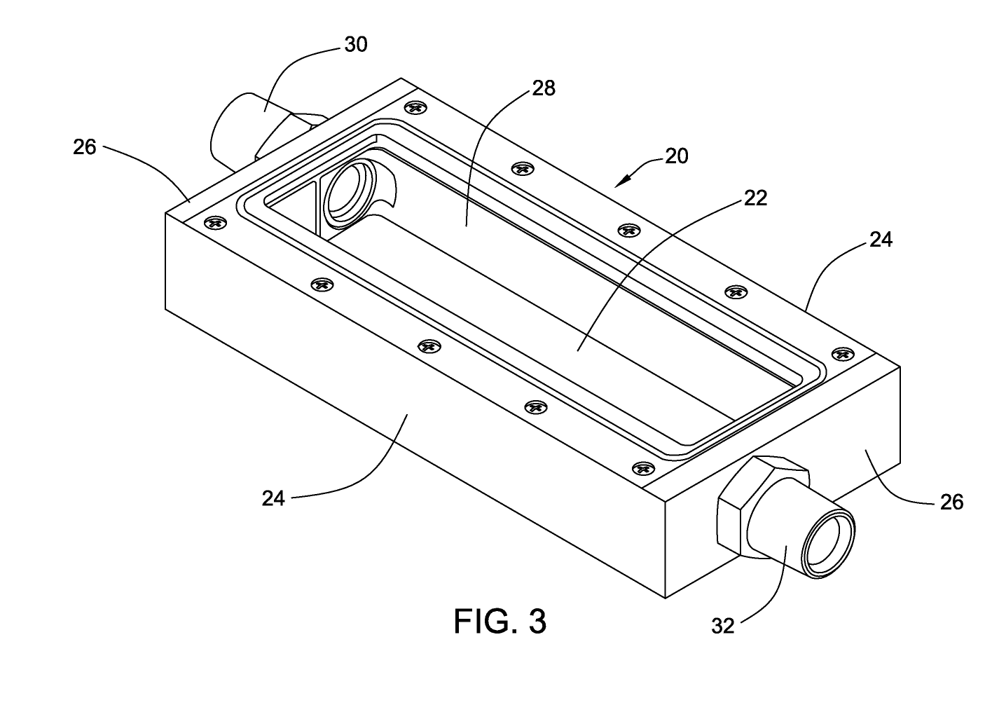

Referring to FIG. 3 of the drawings, a housing or frame 20 of the cooling module 10 is shown to which the electrical component 12 (shown in FIG. 1) may be connected. In the illustrated embodiment, the housing 20 has a generally rectangular box-shaped configuration including a bottom wall 22, two upstanding side walls 24, two upstanding end walls 26 and an open top end. The housing 20 can define an interior space 28 for receiving a coolant, such as a cooling liquid, and through which the coolant may flow. To this end, the housing 20 may include a coolant inlet 30 in one of the end walls 26 that communicates with the interior space 28 and a coolant outlet 32 in the opposing end wall 26 that also communicates with the interior space 28. More specifically, fresh coolant may be directed under pressure, such as by a pump, into the interior space 28 of the housing 20 through the coolant inlet 30. The used, heated coolant may subsequently be drawn out of the interior space 28 of the housing 20 through the coolant outlet 32. In an known manner, the used, heated coolant may be cooled and then recycled through the interior space via the fluid inlet. The terms inlet and outlet are for references purposes only and coolant flow through the cooling module 10 could be in either direction in different embodiments.

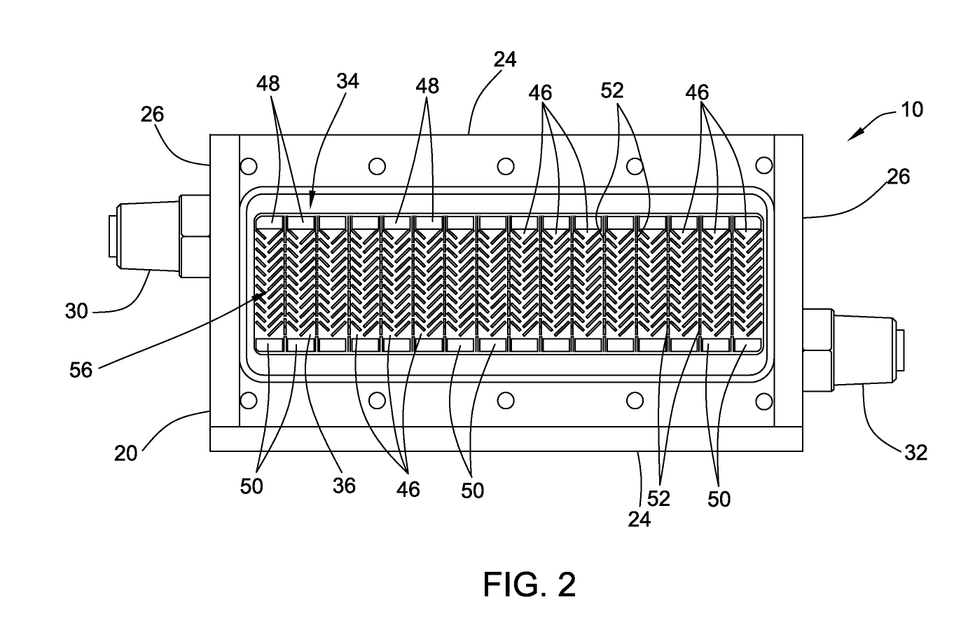

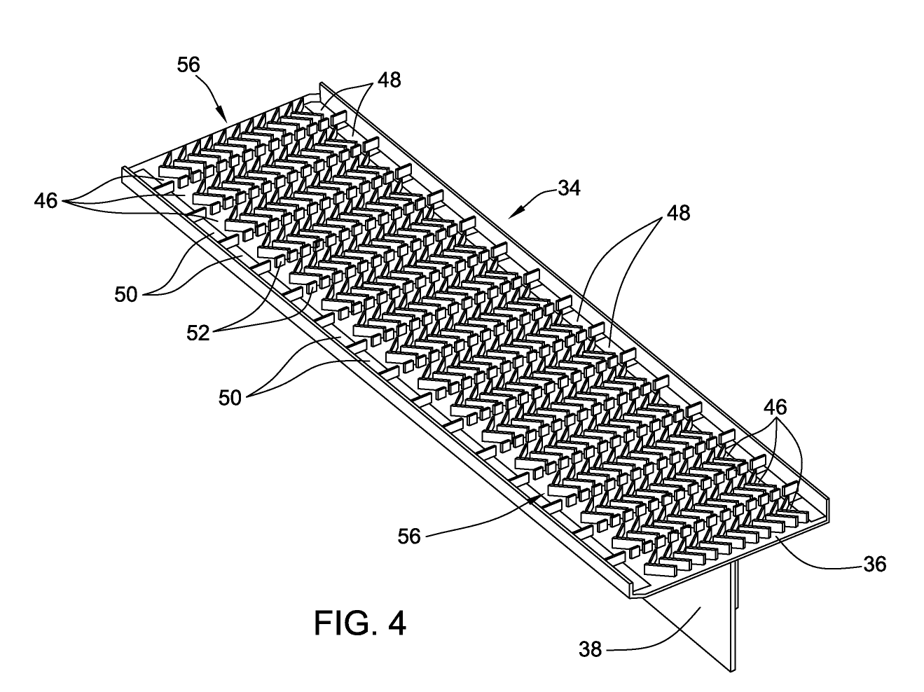

For helping direct the flow of coolant through the cooling module 10, a flow directing member 34 may be provided in the interior space 28 defined by the housing 20. As shown in FIG. 4, the flow directing member 34 may have a T-shaped configuration with an upper plate 36 and a downwardly extending leg 38. The flow directing member 34 may be arranged in the interior space 28 of the housing 20 with the upper plate 36 of the flow directing member near the open upper end of the housing 20 (see FIGS. 2 and 6) and with the leg 38 extending downward so as to divide the interior space 28 beneath the plate 36 into two chambers (see FIG. 6). To this end, the leg 36 of the flow directing member 34 may be configured to extend the longitudinal length of the housing 20 (see FIG. 4) between the two end walls 26 and to extend downward to the bottom wall 22 of the housing 20 (see FIG. 6). In this case, the lower edge of the leg 36 can be received in a groove 40 in the bottom wall 22 of the housing 20 as shown in FIG. 6. The inlet 30 is arranged on the end wall 26 of the housing 20 such that coolant entering the housing is received in the chamber on one side of the leg 38 of the flow directing member 34. Similarly, the outlet 32 is arranged on the opposing end wall 26 of the housing 20 such that coolant is removed from the chamber on the other side of the leg 38. Alternatively, the inlet 30 and outlet 32 may be provided on the same end of the housing with each communicating with a chamber on a respective side of the leg 38. Thus, as shown in FIG. 6, one of the chambers defined by the leg 38 can be considered the inlet chamber 42 while the chamber defined on the other side of the leg 38 can be considered the outlet chamber 44. In other embodiments, the inlet and outlet sides of the leg 38 of the flow directing member 34 may be switched.

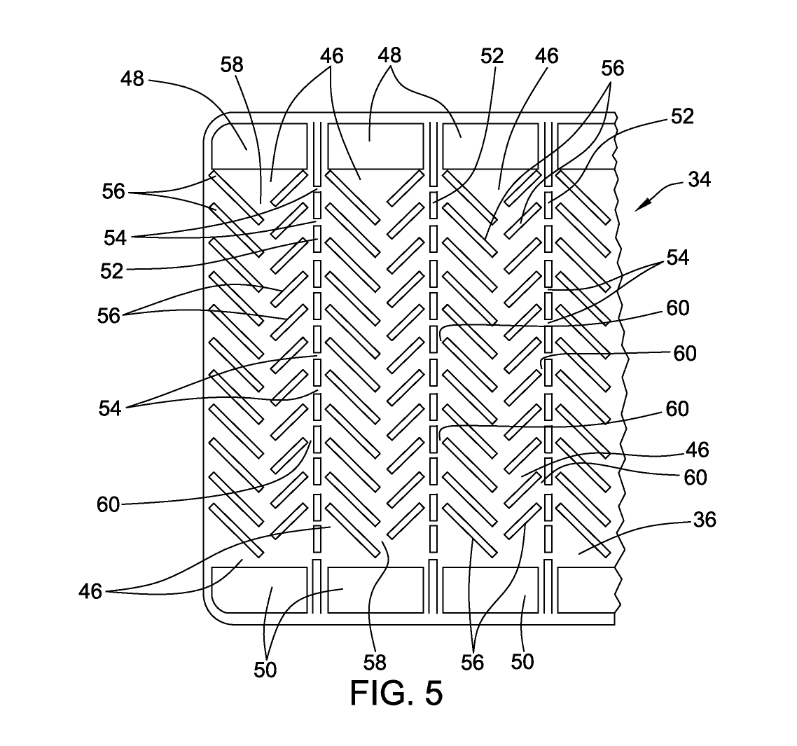

For directing the flow of coolant near the upper end of the housing 20 and adjacent the underside of the base plate 18 of the electrical component 12, an upper surface of the plate 36 of the flow directing member 34 may be divided into a plurality of individual cells 46 arranged in parallel. As best shown in FIG. 5, adjacent cells 46 may be separated from each other by dividing walls 52 as described in more detail below. The parallel arrangement of the cells 46 reduces the pressure drop of the coolant between the inlet 30 and outlet 32 of the housing 20 as compared to cells arranged in series. As best shown in FIG. 5, each cell 46 may include an inlet opening 48 in the plate 36 at one longitudinal side thereof that communicates with the inlet chamber 42 of the housing 20. Each cell 46 may further include an outlet opening 50 in the plate 36 at the opposing longitudinal side thereof that communicates with the outlet chamber 44 of the housing 20. In operation, coolant may be drawn or directed into each cell 46 on the surface of the plate 36 from the inlet chamber 42 through the respective inlet opening 48. The coolant may then flow over the surface of the plate 36 through each cell 46 in a downstream direction from the inlet opening 48 to the outlet opening 50. The coolant may then be drawn out of or directed off the cell 46 through the respective outlet opening 50 and into the outlet chamber 44 where it can exit the housing 20 through the outlet 32.

As noted above, dividing walls 52 can separate adjacent cells 46 from one another. In order to help balance the pressure between adjacent cells 46, each dividing wall 52 may have a plurality of openings 54 therein as best shown in FIG. 5. With such an arrangement, the cells 46 are discrete from one another but they are also fluidly connected. Fluidly connecting the individual cells 46 with each other helps ensure an even pressure distribution across the plurality of cells 46. The even pressure distribution, in turn, leads to equalized coolant flow rates through the individual cells 46 which helps prevent hot spots in the cooling module 10. To further enhance cooling performance, dividing walls may not be provided at either longitudinal end of the plate leaving the corresponding first and last cells 46 on the plate substantially open on one edge as shown in FIG. 4. This arrangement can effectively increase the heat transfer area provided on the surface of the plate 36 because it exposes more of the electrical component 12 to the coolant which has a significantly higher heat transfer than the material used to construct the dividing walls.

To facilitate the generation of vortices in the flow of coolant through the cells 46, each cell 46 can include a plurality of coolant mixing fins 56 that are arranged in a herringbone pattern. More specifically, each cell 46 may include a plurality of first fins 56 arranged in a row that extends in the downstream direction (i.e., the direction starting at the inlet opening and extending towards the outlet opening) and a plurality of second fins 56 arranged in a second row extending in the downstream direction. Each fin 56 in each row angles in the downstream direction as it extends from an edge of the cell 46 toward the center of the cell 46. In the illustrated embodiment, each fin 56 in the first row is paired with an opposing fin 56 in the second row that together form a V-shape. As best shown in FIG. 5, the V-shape formed by the opposing fins 56 is broken by a flow opening 58 between the opposing fins 56. In the case of the illustrated embodiment, the fins 56 in one row are relatively longer than the fins 56 in the other row. Additionally, the flow openings 58 are near the center of the cell 46. However, other configurations could also be used. The herringbone arrangement of the fins 56 produces vortices in the flow through the cells 46 which mixes the coolant and leads to better to cooling performance. Moreover, the herringbone pattern of the fins 56 can reduce the flow resistance of the flow directing member 34 which can help reduce the pressure drop between the inlet 30 and the outlet 32 of the cooling module housing 20. Herringbone patterns other than that shown in the illustrated embodiment may also be used such as arrangements with more than two rows of fins 56 in each cell and/or arrangements that alternate between the first and second fins 56 which fin is longer in each opposing pair.

To provide further enhancement of the vortex mixing, the fins 56 may be arranged and configured such that the fins 56 do not intersect with the dividing walls 52 between the cells 46. More particularly, as shown in FIG. 5, the fins 56 next to a dividing wall 52 may be spaced from the dividing wall such that an opening 60 is provided between the end of the fin 56 nearest the dividing wall 52 and the dividing wall 52. These openings 60 can help prevent recirculation of the flow of coolant in the individual cells 46. For example, if openings 60 are not provided, the channels defined between adjacent fins 56 in the direction of flow would dead end at the dividing wall 52. Such dead ends could hamper downstream flow and cause the coolant to re-circulate in the region between adjacent fins 56, potentially leading to local high coolant temperatures and pressures. The openings 60 between the ends of the fins 56 and the dividing walls 52 can create further vortex mixing of the coolant that can help prevent the flow of coolant from becoming stagnant.

As shown in FIG. 6, to provide for direct cooling of the electrical component 12, the electrical component may be connected to the cooling module 10 in a cooling assembly with the base plate 18 of the electrical component 12 directly exposed to the coolant in the cooling module 10. To this end, the base plate 18 of the electrical component 12 may be connected to the housing 20 of the cooling module 10 with the base plate 18 extending over the open upper side of the housing 20. Exposing the base plate 18 of the electrical component 12 directly to the flow of coolant can provide improved cooling performance as compared to arrangements involving intermediate layers between the coolant and the electrical component. Additionally, as shown in FIG. 6, the plate 36 of the flow directing member 34 may be configured such that there is a gap 62 between the uppermost edge of the fins 56 (and possibly the dividing walls 52) on the surface of the plate 36 and the underside of the electrical component 12 when it is mounted to the cooling module 10. This gap 62 can helps increase local coolant flow velocity resulting in a higher local convective heat transfer.

### INDUSTRIAL APPLICABILITY

The present disclosure is applicable to the cooling of any type of electrical component. The cooling module of the present disclosure is particularly applicable to high performance electrical components, such as IGBTs and other electrical components used in an electric propulsion system for a machine or in an electric generator, that produce a significant amount of heat during operation. The enhanced cooling performance that is provided by, for example, the herringbone configuration of the flow directing fins, provides enhanced cooling performance that helps ensure that such electric components operate at their peak operating conditions and reliability. Additionally, the configuration of the cooling module, helps ensure a low pressure drop in the coolant between the inlet and outlet sides of the cooling module. As a result, less pump power may be required to move the coolant through the cooling module, which can lead to lower costs. The low pressure drop also reduces stress on the components associated with transferring the coolant to and from the cooling module, such as hoses, gaskets and seals.

It will be appreciated that the foregoing description provides examples of the disclosed system and technique. However, it is contemplated that other implementations of the disclosure may differ in detail from the foregoing examples. All references to the disclosure or examples thereof are intended to reference the particular example being discussed at that point and are not intended to imply any limitation as to the scope of the disclosure more generally. All language of distinction and disparagement with respect to certain features is intended to indicate a lack of preference for those features, but not to exclude such from the scope of the disclosure entirely unless otherwise indicated.

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context.

We claim:

1. A cooling module for an electrical component comprising:
a housing defining an interior space for receiving a coolant, the housing having an inlet for directing coolant into the interior space and an outlet for removing coolant from the interior space; and
a flow directing member arranged in the interior space of the housing, the flow directing member including a plate that is divided into a plurality of discrete cells arranged parallel to each other, adjacent cells being separated from each other by a dividing wall;
wherein each cell has an inlet opening in the plate through which coolant is directed onto a surface of the plate and an outlet opening in the plate through which coolant is directed off the surface of the plate, each cell having a plurality of fins arranged on the surface of the plate in a herringbone pattern, the plurality of fins including a plurality of first fins arranged in a first row extending in a downstream direction from the inlet opening in the respective cell to the outlet opening in the respective cell and a plurality of second fins arranged in a second row extending in the downstream direction, each first fin having an opposing second fin that together form a V-shape that is broken by a flow opening between the first and second fins, and each first and second fin being angled in a downstream direction as it extends from an edge of the cell towards a center of the cell.

2. The cooling module of claim 1 wherein each dividing wall has a plurality of openings therethrough such that the cells are fluidly connected to each other.

3. The cooling module of claim 1 wherein each fin that is arranged next to one of the dividing walls is spaced from the respective dividing wall such that there is an opening between an end of the fin nearest the dividing wall and the dividing wall.

4. The cooling module of claim 1 wherein the housing has an open top and the housing is configured such that an electrical component is connectable to the housing with the electrical component extending over the open top of the frame.

5. The cooling module of claim 4 wherein the plate is arranged near the open top of the housing.

6. The cooling module of claim 4 wherein the fins and dividing walls are configured such that there is a gap between an underside of an electrical component and respective upper edges of the fins when the electrical component is connected to the housing.

7. The cooling module of claim 1 wherein the second fins are longer than the first fins.

8. The cooling module of claim 1 wherein the cells at opposing ends of the plate have an open edge.

9. The cooling module of claim 1 wherein the flow directing member includes a leg that extends away from the plate, the leg dividing the interior space of the housing into a inlet chamber in communication with the housing inlet and the inlets to the respective cells and an outlet chamber in communication with the housing outlet and the outlets to the respective cells.

10. A cooling module for an electrical component comprising:
a housing defining an interior space for receiving a coolant, the housing having an inlet for directing coolant into the interior space and an outlet for removing coolant from the interior space; and
a flow directing member arranged in the interior space of the housing, the flow directing member including a plate that is divided into a plurality of discrete cells arranged parallel to each other, adjacent cells being separated from each other by a dividing wall having a plurality of openings therethrough such that the cells are fluidly connected to each other;
wherein each cell has an inlet opening in the plate through which coolant is directed onto a surface of the plate and an outlet opening in the plate through which coolant is directed off the surface of the plate, each cell having a plurality of fins arranged on the surface of the plate in a herringbone pattern, the plurality of fins including a plurality of first fins arranged in a first row extending in a downstream direction from the inlet opening in the respective cell to the outlet opening in the respective cell and a plurality of second fins arranged in a second row extending in the downstream direction, each first fin having an opposing second fin that together form a V-shape that is broken by a flow opening between the first and second fins, each first and second fin being angled in a downstream direction as it extends from an edge of the cell towards a center of the cell, and each fin that is arranged next to one of the dividing walls being spaced from the respective dividing wall such that there is an opening between an end of the fin nearest the dividing wall and the dividing wall.

11. The cooling module of claim 10 wherein the housing has an open top and the housing is configured such that an electrical component is connectable to the housing with the electrical component extending over the open top of the frame.

12. The cooling module of claim 11 wherein the plate is arranged near the open top of the housing.

13. The cooling module of claim 11 wherein the fins and dividing walls are configured such that there is a gap between an underside of an electrical component and respective upper edges of the fins when the electrical component is connected to the housing.

14. The cooling module of claim 10 wherein the second fins are longer than the first fins.

15. The cooling module of claim 10 wherein the cells at opposing ends of the plate have an open edge.

16. The cooling module of claim 10 wherein the flow directing member includes a leg that extends away from the plate, the leg dividing the interior space of the housing into a inlet chamber in communication with the housing inlet and the inlets to the respective cells and an outlet chamber in communication with the housing outlet and the outlets to the respective cells.

17. A cooling assembly comprising:
an electrical component including a base plate; and
a cooling module, the cooling module comprising:
a housing having an open top, the housing being connected to the electrical component with the base plate extending over the open top of the housing, the housing defining an interior space for receiving a coolant, the housing having an inlet for directing coolant into the interior space and an outlet for removing coolant from the interior space; and
a flow directing member arranged in the interior space of the housing, the flow directing member including a plate arranged near the open top of the housing that is divided into a plurality of discrete cells arranged parallel to each other, adjacent cells being separated from each other by a dividing wall having a plurality of openings therethrough such that the cells are fluidly connected to each other;
wherein each cell has an inlet opening in the plate through which coolant is directed onto a surface of the plate and an outlet opening in the plate through which coolant is directed off the surface of the plate, each cell having a plurality of fins arranged on the surface of the plate in a herringbone pattern, the plurality of fins including a plurality of first fins arranged in a first row extending in a downstream direction from the inlet opening in the respective cell to the outlet opening in the respective cell and a plurality of second fins arranged in a second row extending in the downstream direction, each first fin having an opposing second fin that together form a V-shape that is broken by a flow opening between the first and second fins, each first and second fin being angled in a downstream direction as it extends from an edge of the cell towards a center of the cell, and each fin that is arranged next to one of the dividing walls being spaced from the respective dividing wall such that there is an opening between an end of the fin nearest the dividing wall and the dividing wall.

18. The cooling assembly of claim 17 wherein the fins and dividing walls are configured such that there is a gap between an underside of the base plate and respective upper edges of the fins.

19. The cooling module of claim 10 wherein the cells at opposing ends of the plate have an open edge.

20. The cooling module of claim 10 wherein the flow directing member includes a leg that extends away from the plate, the leg dividing the interior space of the housing into a inlet chamber in communication with the housing inlet and the inlets to the respective cells and an outlet chamber in communication with the housing outlet and the outlets to the respective cells.
